(19) United States
(12) Patent Application Publication
(10) Pub. No.: US 2025/0221031 A1
(43) Pub. Date: Jul. 3, 2025

(54) SEMICONDUCTOR STRUCTURE AND METHOD FOR MANUFACTURING THE SAME

(71) Applicant: INSTITUTE OF MICROELECTRONICS, CHINESE ACADEMY OF SCIENCES, Beijing (CN)

(72) Inventors: Huaxiang Yin, Beijing (CN); Yadong Zhang, Beijing (CN); Qingzhu Zhang, Beijing (CN); Feixiong Wang, Beijing (CN); Yunjiao Bao, Beijing (CN)

(21) Appl. No.: 18/767,219

(22) Filed: Jul. 9, 2024

(30) Foreign Application Priority Data
Dec. 29, 2023 (CN) 202311869432.1

(51) Int. Cl. H01L 27/092; H01L 21/822; H01L 21/8238; H01L 29/06; H01L 29/417; H01L 29/423; H01L 29/66; H01L 29/775; H01L 29/786

(52) U.S. Cl. CPC H10D 84/856; H10D 30/014; H10D 30/43; H10D 30/6729; H10D 30/6735; H10D 30/6757; H10D 62/121; H10D 64/017; H10D 84/0186; H10D 84/038; H10D 88/01

(57) ABSTRACT

A semiconductor structure and a method for manufacturing the same. The method comprises: providing a substrate comprising a first surface and a second surface opposite to each other; forming, on the first surface, a first transistor structure comprising a first channel layer, a first gate structure disposed on the first channel layer, and a first source-drain epitaxial layer disposed on two lateral sides of the first gate structure; providing, on the second surface, a second transistor structure comprising a second channel layer, a second gate structure disposed on the second channel layer, and a second source-drain epitaxial layer disposed on two lateral sides of the second gate structure; forming, in the second source-drain epitaxial layer and the substrate, a first conductive plug electrically connected to the first source-drain epitaxial layer; and forming a first interconnection layer on the first conductive plug and the second gate structure.

This application claims priority to Chinese Patent Application No. 202311869432.1, titled “SEMICONDUCTOR STRUCTURE AND METHOD FOR MANUFACTURING THE SAME”, filed on Dec. 29, 2023, with the China National Intellectual Property Administration, which is incorporated herein by reference in its entirety.

### FIELD

The present disclosure relates to the technical field of semiconductor manufacturing, and in particular to a semiconductor structure and a method for manufacturing the semiconductor structure.

### BACKGROUND

Development of semiconductor technology requires higher integration density and a smaller loss of a voltage provided by a power source. Through appropriate techniques, a power distribution network (PDN) in traditional backend of the line (BEOL) schemes may be allocated to a backside of a wafer to achieve a power backside power distribution network (BS-PDN), which has attracted increasing attention.

The BS-PDNs have significantly higher integration density and significantly smaller voltage loss on interconnections in view of front-side power distribution network (FS-PDNs) and improved FS-PDNs using buried power rails (BPRs).

In conventional technology, a large distance is required for inter-layer isolation in the power distribution networks, which brings difficulties to improving an integration degree of semiconductor structures.

### SUMMARY

A semiconductor structure and a method for manufacturing the semiconductor are provided according to embodiments of the present disclosure. A first transistor and a second transistor are bonded to opposite sides, respectively, of a substrate. A first interconnection layer is formed on the first transistor, and a second interconnection layer is formed on the second transistor. Compared with a scheme of bonding the second transistor and the first transistor at a same side of the substrate, a distance between the first transistor and the second transistor can be reduced, and an integration density of semiconductor structures can be increased.

A method for manufacturing a semiconductor structure is provided according to an embodiment of the present disclosure. The method comprises: providing a substrate comprising a first surface and a second surface that are opposite to each other; providing a first transistor structure on the first surface, where the first transistor structure comprises: a first channel layer disposed on the first surface, a first gate structure disposed on a surface of the first channel layer, and a first source-drain epitaxial layer disposed on two lateral sides of the first gate structure; providing a second transistor structure on the second surface, where the second transistor structure comprises: a second channel layer disposed on the second surface, a second gate structure disposed on a surface of the second channel layer, and a second source-drain epitaxial layer disposed on two lateral sides of the second gate structure; providing a first conductive plug in the second source-drain epitaxial layer and the substrate, where the first conductive plug is electrically connected to the first source-drain epitaxial layer; providing a first interconnection layer on a side of the second transistor structure away from the second surface, where the first interconnection layer is electrically connected to the first conductive plug.

In an embodiment, providing the second transistor structure on the second surface of the substrate comprises bonding the second channel layer to the second surface. After providing the first transistor structure on the first surface and before providing the second transistor structure on the second surface, the method further comprises: flipping an integral structure comprising the first transistor structure and the substrate.

In an embodiment, the first channel layer comprises a first fin disposed on the first surface.

In an embodiment, the first channel layer comprises multiple first stacking layers of nanowires disposed on the first surface, where each pair of adjacent layers in the multiple first stacking layers is spaced apart.

In an embodiment, the second channel layer comprises a second fin disposed on the second surface.

In an embodiment, the second channel layer comprises multiple second stacking layers of nanowires disposed on the second surface, where each pair of adjacent layers in the multiple second stacking layers is spaced apart.

In an embodiment, forming the first channel layer comprises: providing an initial substrate; forming initial stacking layers on a surface of the initial substrate; forming a first mask layer on a surface of the initial stacking layers; patterning the initial stacking layers and the initial substrate with masking of the first mask layer to form the substrate and an initial first channel layer located on a surface of the substrate, where the initial first channel layer comprises at least one channel material layer and at least one sacrificial material layer that are overlapped and alternately arranged; forming an isolation structure on the substrate; forming a dummy gate and spacers on the initial first channel layer, where the spacers are located on two lateral sides of the dummy gate; forming a source-drain opening in the initial first channel layer after forming the dummy gate; forming the first source-drain epitaxial layer in the source-drain opening; removing, after forming the first source-drain epitaxial layer, the dummy gate and the at least one sacrificial material layer to form a gate opening; and forming the first gate structure and the first channel layer in the gate opening, where the first gate structure is located on the surface of the first channel layer.

In an embodiment, after forming the first gate structure and the first channel layer, the method further comprises: forming a first dielectric layer at a side of the first transistor structure away from the first surface; forming a second conductive plug in the first dielectric layer; and forming a second interconnection layer on the second conductive plug, where the second interconnection layer is electrically connected to one or both of the first source-drain epitaxial layer and the first gate structure, and the second conductive plug is electrically connected to the second interconnection layer.

In an embodiment, after flipping the integral structure comprising the substrate and the first transistor structure and before providing the second transistor structure on the second surface of the substrate, the method further comprises: forming a first bonding layer on a surface of the second interconnection layer; bonding a carrier wafer to the first bonding layer bonded to the first bonding layer; thinning the substrate from the second surface toward the first surface; and forming an isolation dielectric layer on the second surface after the thinning.

In an embodiment, the second transistor structure is bonded to a surface of the isolation dielectric layer away from the second surface. A thickness of the isolation dielectric layer may range from 1 nm to 10000 nm.

In an embodiment, a temperature of the bonding is less than 500° C.

In an embodiment, a thickness of the substrate after the thinning ranges from 10 nm to 100000 nm.

In an embodiment, the method further comprises: forming a third conductive plug running through the second source-drain epitaxial layer, the substrate, and the first source-drain epitaxial layer.

A semiconductor structure is further provided according to an embodiment of the present disclosure. The semiconductor structure comprises: a substrate, comprising a first surface and a second surface opposite to each other; a first transistor structure disposed on the first surface, where the first transistor structure comprises: a first channel layer disposed on the first surface, a first gate structure disposed on a surface of the first channel layer, and a first source-drain epitaxial layer disposed on two lateral sides of the first gate structure; a second transistor structure disposed on the second surface, where the second transistor structure comprises: a second channel layer disposed on the second surface, a second gate structure disposed on a surface of the second channel layer, and a second source-drain epitaxial layer disposed on two lateral sides of the second gate structure; a first conductive plug disposed in the second source-drain epitaxial layer and the substrate, where the first conductive plug is electrically connected to the first source-drain epitaxial layer; and a first interconnection layer disposed at a side of the second transistor structure away from the second surface, where the first interconnection layer is electrically connected to the first conductive plug.

In an embodiment, the first channel layer comprises a first fin disposed on the first surface.

In an embodiment, the first channel layer comprises multiple first stacking layers of nanowires disposed on the first surface, where each pair of adjacent layers in the multiple first stacking layers is spaced apart.

In an embodiment, the second channel layer comprises a second fin disposed on the second surface.

In an embodiment, the second channel layer comprises multiple second stacking layers of nanowires disposed on the second surface, where each pair of adjacent layers in the multiple second stacking layers is spaced apart.

In an embodiment, the semiconductor structure further comprises a second interconnection layer disposed at a side of the first transistor structure away from the first surface, where the second interconnection layer is electrically connected to one or both of the first source-drain epitaxial layer and the first gate structure.

In an embodiment, the substrate comprises a base and a bottom structure disposed on the base. The first channel layer is disposed on the bottom structure.

In an embodiment, the semiconductor structure further comprises: a first dielectric layer disposed on a surface of the first source-drain epitaxial layer; and a second conductive plug disposed in the first dielectric layer, where the second conductive plug is electrically connected to the second interconnection layer.

In an embodiment, the semiconductor structure further comprises an isolation dielectric layer disposed between the second surface of the substrate and the second source-drain epitaxial layer. A thickness of the isolation dielectric layer may range from 1 nm to 10000 nm.

In an embodiment, the semiconductor structure further comprises a second dielectric layer disposed on a surface of the second source-drain epitaxial layer. The first conductive plug is further disposed in the second dielectric layer.

In an embodiment, a material of the second transistor structure comprises silicon, germanium, silicon germanium, indium-gallium-zinc oxide, or carbon nanotubes. In an embodiment, a thickness of the substrate ranges from 10 nm to 100000 nm.

In an embodiment, the semiconductor structure further comprises a third conductive plug running through the second source-drain epitaxial layer, the substrate, and the first source-drain epitaxial layer.

In an embodiment, the semiconductor structure further comprises an isolation structure disposed on the substrate, and a part of the first gate structure is disposed on a surface of the isolation structure.

The technical solutions of embodiments of the present disclosure are advantageous over the conventional technology in at least following aspects.

Herein the first transistor structure and the second transistor structure are bonded to opposite sides of the substrate. Compared with conventional semiconductor structures in which two transistors are bonded to the same surface of a substrate, a distance between the first transistor structure and the second transistor structure can be reduced, and a distance between the first transistor structure and the first interconnection layer can also be reduced. An integration degree of the semiconductor structure is thus improved.

Moreover, the semiconductor structure may comprise the second interconnection layer on the second conductive plug, and the second interconnection layer may be electrically connected to the second conductive plug and one or both of the first source-drain epitaxial layer and the first gate structure. Although the first transistor structure and the second transistor structure are bonded to opposite sides of the substrate, a distance between the second transistor structure and the second interconnection layer can also be reduced in comparison with conventional semiconductor structures in which two transistors are bonded to the same surface. Hence, the integration degree of the semiconductor structure is further improved.

Moreover, since the second conductive plug and the second interconnection layer are disposed on the first surface of the substrate, there are adequate spaces for arranging the first transistor structure and the second transistor structure. A depth of the second conductive plug is reduced, and hence a voltage loss on conductive plugs can be reduced in the semiconductor structure.

### BRIEF DESCRIPTION OF THE DRAWINGS

FIGS. 1 to 36 are schematic cross-sectional diagrams of structures during a process of manufacturing a semiconductor structure according to embodiments of the present disclosure.

### DETAILED DESCRIPTION OF EMBODIMENTS

As described in the background, the conventional technology is limited due to various issues. As an example, a first transistor may be formed on a substrate, while a second transistor may be formed on the first transistor. That is, the first transistor and the second transistor are located on the same side of the substrate. In such case, there would be a distance between the first transistor and the second transistor, which hinders improving an integration degree of the semiconductor structure. Moreover, conductive plugs formed in the two transistors would have large depths, which results in a large voltage loss and unstable performances of the semiconductor structure.

A method for manufacturing a semiconductor structure is provided according to embodiments of the present disclosure. A first transistor structure and a second transistor structure are provided on opposite sides of the substrate. In comparison with the case in which the two transistors are disposed on the same side, a distance between the first transistor structure and the second transistor structure, a distance between the first transistor structure and a first interconnection layer, and a distance between the second transistor structure and a second interconnection layer are all reduced. Hence, an integration density of the semiconductor structure is increased. Moreover, since a second conductive plug and the second interconnection layer are disposed on a first surface of the substrate, there are adequate spaces for arranging the first transistor structure and the second transistor structure. Thus, a depth of the second conductive plug is reduced, and a voltage loss is reduced in the semiconductor structure.

Hereinafter embodiments of the present disclosure would be described in conjunction with the drawings to clarify objectives, features, and beneficial effects of the present disclosure.

A substrate 103 is provided. The substrate comprises a first surface and a second surface that are opposite to each other. A first transistor structure is formed on the first surface. The first transistor structure comprises a first channel layer 118 disposed on the first surface, a first gate structure 117 disposed on a surface of the first channel layer 118, and a first source-drain epitaxial layer 114 disposed on two lateral sides of the first gate structure 117. A process of forming the first channel layer 118 comprises following steps. An initial substrate 100 is provided. Multiple initial stacking layers are formed on a surface of the initial substrate 100. A first mask layer is formed on a surface of the initial stacking layers. The initial stacking layers and the initial substrate 100 are patterned with masking of the first mask layer to form the substrate 103 and an initial first channel layer 104 that is located on the surface of the substrate 103. The substrate 103 comprises a base and a bottom structure located on the base.

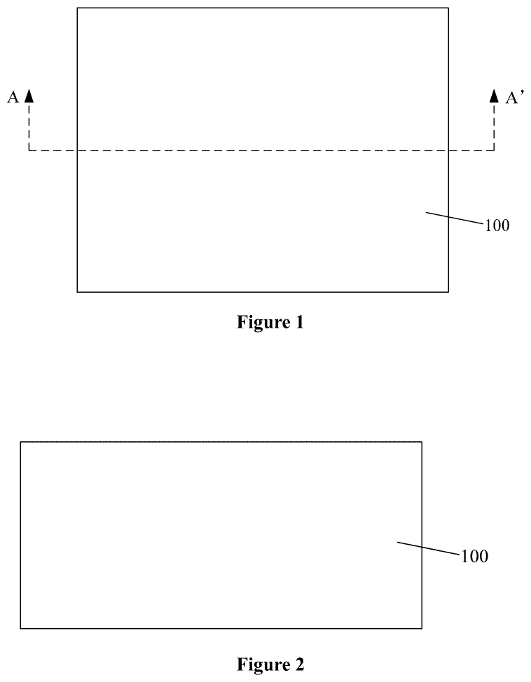

The initial first channel layer 104 comprises at least one channel material layers 106 and at least one sacrificial material layer 105 that are alternately arranged. An isolation structure 107 is formed on the substrate 103. A dummy gate 108 and spacers 109 on two sides of the dummy gate 108 are formed on the initial first channel layer 104. A source-drain opening 110 is formed in the initial first channel layer 104, after the dummy gate 108 has been formed. The first source-drain epitaxial layer 114 are formed in the source-drain opening 110. The dummy gate 108 and the at least one sacrificial material layer 105 are removed to form a gate opening 116, after the first source-drain epitaxial layer 114 has been formed. A first gate structure 117 and a first channel layer 118 are formed the gate opening 116. The first gate structure 117 is located on the surface of the first channel layer 118. Reference may be made to FIGS. 1 to 26.

Reference is first made to FIGS. 1 and 2. FIG. 1 is a top view, and FIG. 2 is a cross-sectional view under cutting line AA′ in FIG. 1. The initial substrate 100 is provided.

A material of the initial substrate 100 may comprises silicon, silicon carbide, silicon germanium, silicon on insulator (SOI), or germanium on insulator (GOI).

In an embodiment, the material of the initial substrate 100 is silicon.

In an embodiment, the method further comprises a following step. A well region is formed in the initial substrate.

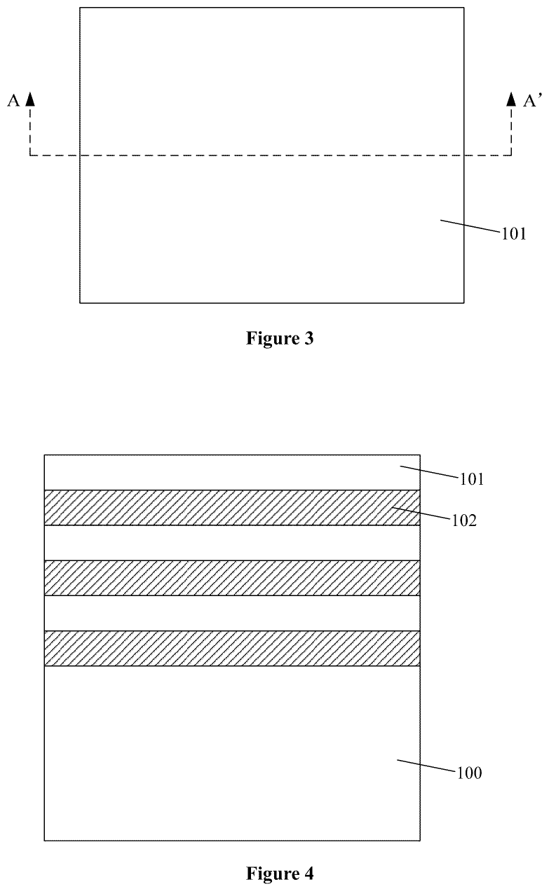

Reference is made to FIGS. 3 and 4. FIG. 3 is a top view, and FIG. 4 is a cross-sectional view under cutting line AA′ in FIG. 3. The initial stacking layers are formed on the surface of the initial substrate 100, and a first mask layer (not depicted) is formed on the surface of the initial stacking layers.

The initial stacking layers comprises initial channel material layer(s) 101 and initial sacrificial material layer(s) 102 that are alternately stacked.

A material of the initial channel material layer 101 may comprise silicon. A material of the initial sacrificial material layer 102 may comprise silicon germanium.

The initial channel material layer(s) 101 are configured to serve as a basis for forming the channel material layer(s) 106 in subsequent steps. The initial sacrificial material layer(s) 102 are configured to serve as a basis for forming the sacrificial material layer(s) 105 in subsequent steps.

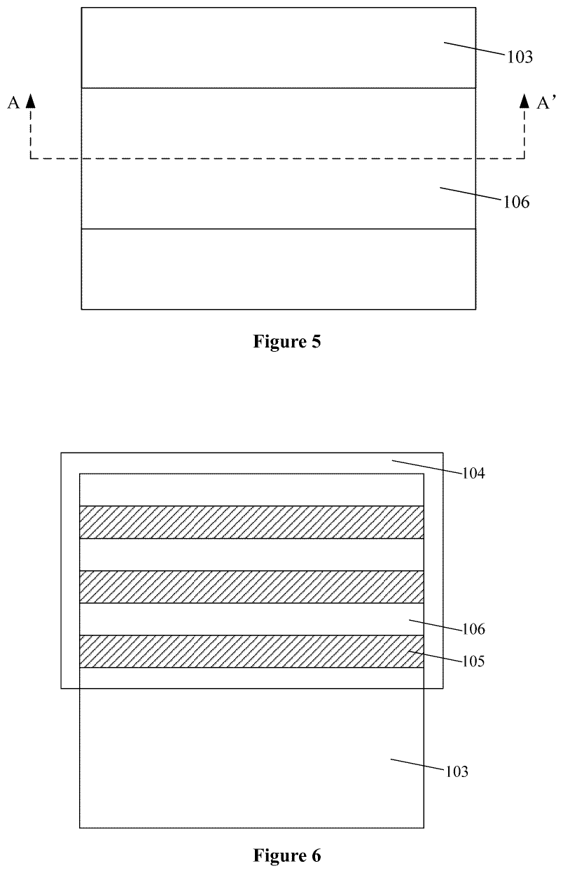

Reference is made to FIGS. 5 and 6. FIG. 5 is a top view, and FIG. 6 is a cross-sectional view under cutting line AA′ in FIG. 5. The initial stacking layers and the initial substrate 100 are patterned with masking of the first mask layer to form the substrate 103 and the initial first channel layer 104. The initial first channel layer 104 is located on the surface of the substrate 103.

The substrate 103 comprises a base (not depicted) and a bottom structure (not depicted) located on the base. The initial first channel layer 104 comprises channel material layer(s) 106 and sacrificial material layer(s) 105 that are alternately arranged.

A material of the channel material layer 106 may comprise silicon. A material of the sacrificial material layer 105 may comprise silicon germanium.

Herein the patterning may adopt multi-patterning techniques, for example, double patterning or quadruple patterning techniques. The multi-patterning is capable to break through the photolithography limitation. Generally, the multi-patterning techniques include lithography and self-aligned double patterning.

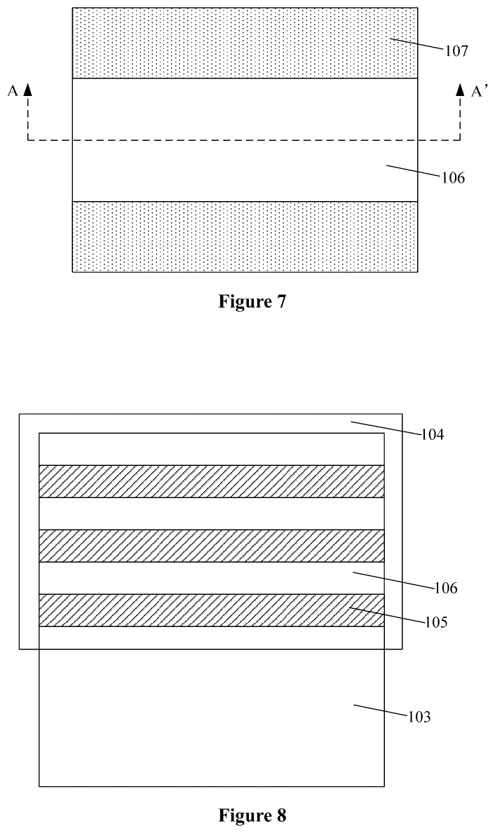

Reference is made to FIGS. 7 and 8. FIG. 7 is a top view, and FIG. 8 is a cross-sectional view under cutting line AA′ in FIG. 7. After the substrate 103 has been formed, an isolation structure 107 may be formed on the substrate 103.

The isolation structure 107 may be formed through low temperature insulating dielectric deposition. The deposition may adopt high aspect ratio process (HARP) or flowable chemical vapor deposition (FCVD) techniques.

A part of the dummy gate 108, which would be formed in a subsequent step, may be located on a surface of the isolation structure 107.

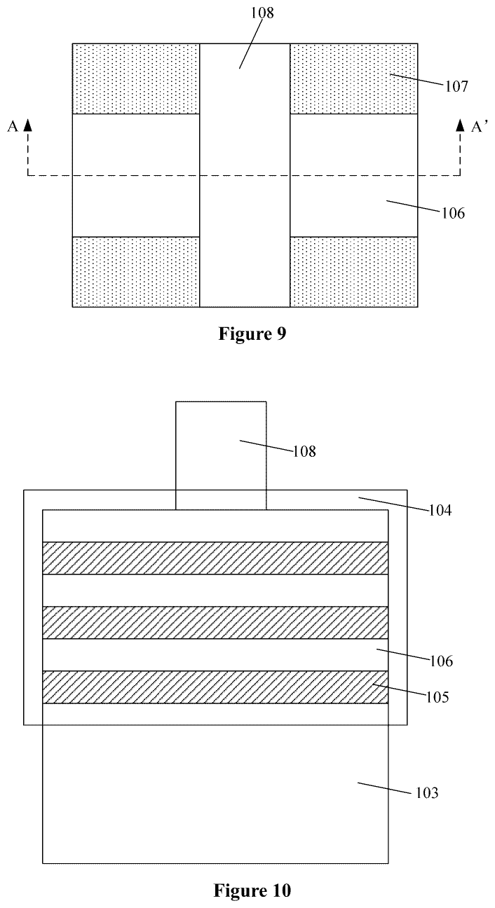

Reference is made to FIGS. 9 and 10. FIG. 9 is a top view, and FIG. 10 is a cross-sectional view under cutting line AA′ in FIG. 9. After the isolation structure 107 has been formed, a dummy gate 108 is formed on the initial first channel layer 104.

In an embodiment, the dummy gate 108 comprises an oxide layer (not depicted) and a dummy-gate layer (not depicted). The dummy-gate layer is located on a surface of the oxide layer.

In an embodiment, a part of the dummy gate 108 is located on a surface of the isolation structure 107.

A material of the dummy-gate layer may comprise polysilicon. A material of the oxide layer may comprise silicon oxide.

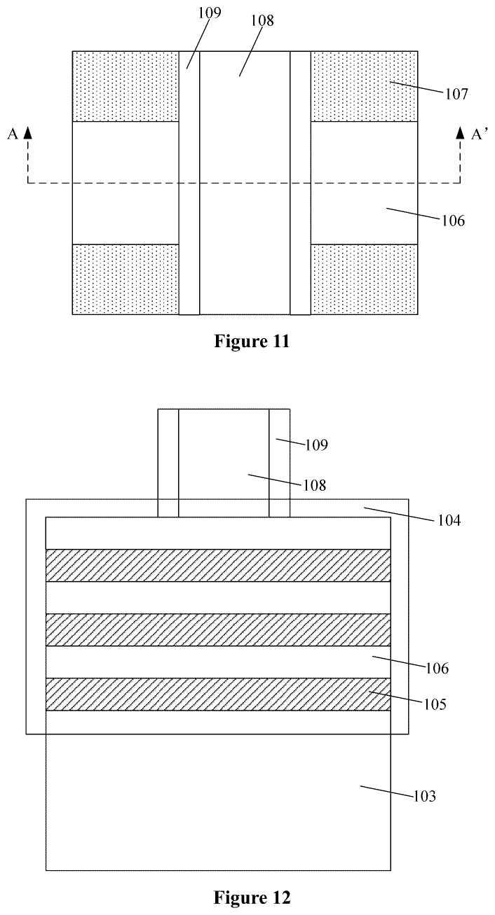

Reference is made to FIGS. 11 and 12. FIG. 11 is a top view, and FIG. 12 is a cross-sectional view under cutting line AA′ in FIG. 11. After the dummy gate 108 has been formed, spacers 109 are formed on two lateral sides of the dummy gate 108.

A material of the spacers 109 may comprise silicon nitride or silicon oxide.

The spacers 109 may be formed through deposition.

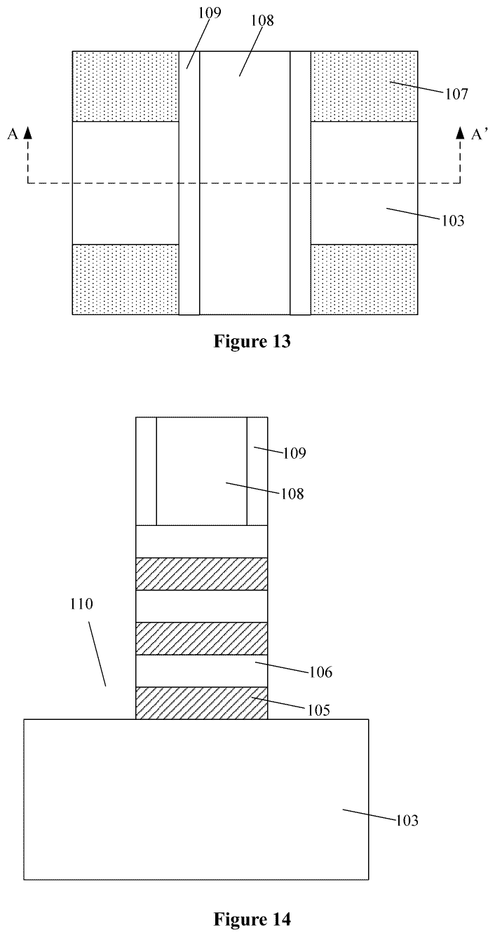

Reference is made to FIGS. 13 and 14. FIG. 13 is a top view, and FIG. 14 is a cross-sectional view under cutting line AA′ in FIG. 13. After the dummy gate 108 and the spacers 109 have been formed, the source-drain openings 110 are formed in the initial first channel layer 104 (which is indicated in FIG. 12).

The source-drain openings 110 are configured to provide a space for forming the first source-drain epitaxial layer 114 in subsequent steps.

A process of forming the source-drain opening 110 may comprises following steps. A second mask layer (not depicted) is formed on a surface of the initial first channel layer 104, and the second mask layer exposes a part of the surface of the initial first channel layer 104. The initial first channel layer 104 is etched with masking of the second mask layer to form the source-drain openings 110.

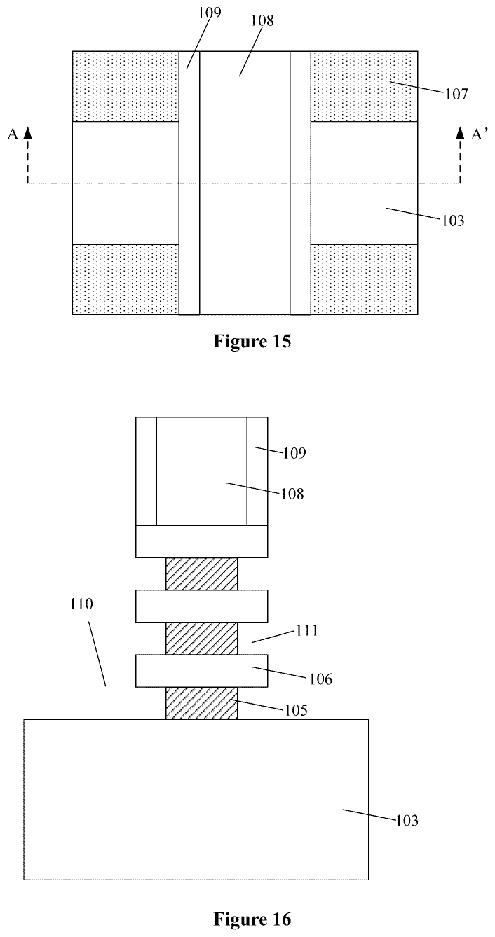

Reference is made to FIGS. 15 and 16. FIG. 15 is a top view, and FIG. 16 is a cross-sectional view under cutting line AA′ in FIG. 15. The sacrificial material layer(s) 105 exposed in the source-drain opening 110 is etched inward to form recesses with respect to sidewalls of the channel material layer(s) 106 exposed in the source-drain openings 110. That is, isolation trench(es) 111 are formed between each pair of adjacent channel material layers 106.

The isolation trench(es) 111 are configured to provide a space for forming isolation layer(s) 113 in subsequent steps.

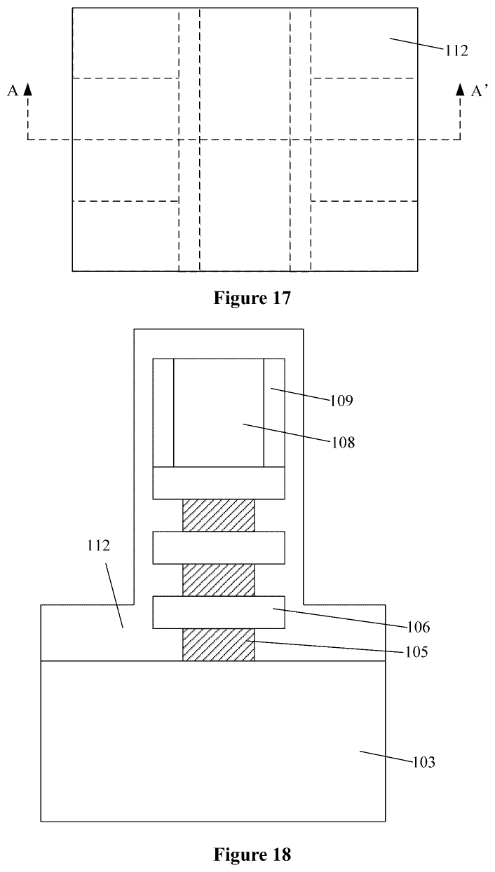

Then, the isolation layer(s) 113 are formed in the isolation trench(es) 111, and a surface of the isolation layer(s) 113 is flush with the respective sidewalls of the channel material layer(s) 106 exposed in the source-drain openings 110. A process of forming the isolation layer(s) 113 may comprise following steps. An isolation material layer 112 is formed on the surface of the substrate 103, in the isolation trench(es) 111, on a surface of the spacers 109, and on top of the dummy gate 108. The isolation material layer 112 is etched until its sidewalls are flush with the sidewalls of the channel material layer(s) 106. At such time, the isolation layer(s) 113 are formed. Reference may be made to FIG. 17 to FIG. 20.

Reference is first made to FIGS. 17 and 18. FIG. 17 is a top view, and FIG. 18 is a cross-sectional view under cutting line AA′ in FIG. 17. The isolation material layer 112 on the surface of the substrate 103, in the isolation trench(es) 111, on a surface of the spacers 109, and on top of the dummy gate 108.

A material of the isolation material layer 112 may comprise silicon nitride, silicon oxide, silicon carbon nitride, silicon carbon oxynitride, silicon oxycarbide, or silicon oxynitride.

The isolation material layer 112 may be formed through deposition.

The isolation material layer 112 is configured to serve as a basis for forming the isolation layer(s) 113.

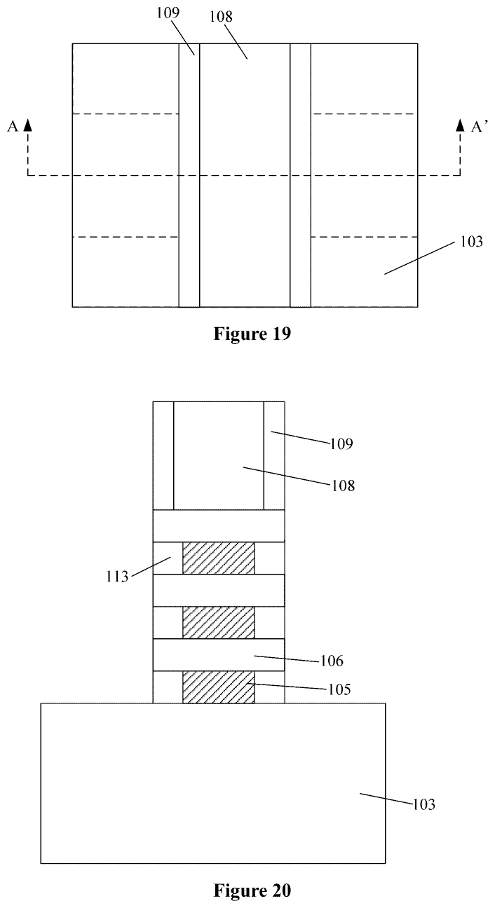

Reference is made to FIGS. 19 and 20. FIG. 19 is a top view, and FIG. 20 is a cross-sectional view under cutting line AA′ in FIG. 19. The etching is performed until the sidewalls of the isolation material layer 112 are flush with the respective sidewalls of the channel material layer(s) 106, such that the isolation layer(s) 113 are formed.

A material of the isolation layer 113 comprises silicon nitride, silicon oxide, silicon carbon nitride, silicon carbon oxynitride, silicon oxycarbide, or silicon oxynitride.

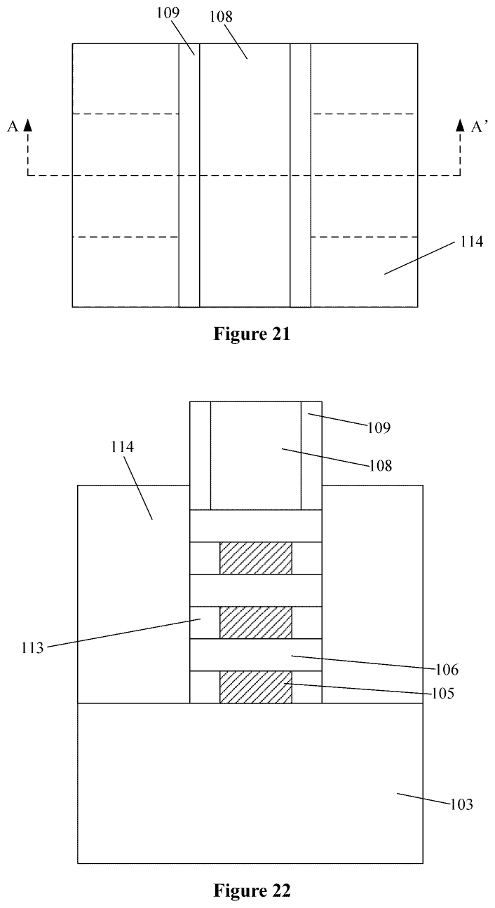

Reference is made to FIG. 21 and FIG. 22. FIG. 21 is a top view, and FIG. 22 is a cross-sectional view under cutting line AA′ in FIG. 21. After the isolation layer 113 has been formed, the first source-drain epitaxial layer 114 is formed in the source-drain openings 110 (which is indicated in FIG. 16).

In a case that the channel material layer 106 is configured to provide a p-channel, a material of the first source-drain epitaxial layer 114 may comprises silicon germanium. In a case that the channel material layer 106 configured to provide an n-channel, a material of the first source-drain epitaxial layer 114 comprises silicon.

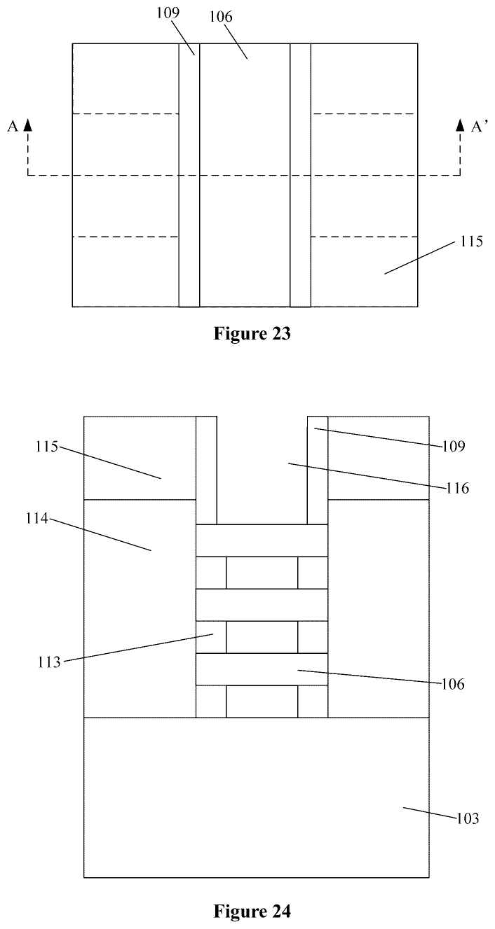

Reference is made to FIGS. 23 and 24. FIG. 23 is a top view, and FIG. 24 is a cross-sectional view under cutting line AA′ in FIG. 23. After the first source-drain epitaxial layer 114 has been formed, a third dielectric layer 115 is formed on a surface of the first source-drain epitaxial layer 114. After the third dielectric layer 115 has been formed, the dummy gate 108 (which is indicated in FIG. 22) and the sacrificial material layer(s) 105 (which are indicated in FIG. 22) are removed to form a gate opening 116.

The gate opening 116 is configured to provide a space for forming the first gate structure 117 and the first channel layer 118.

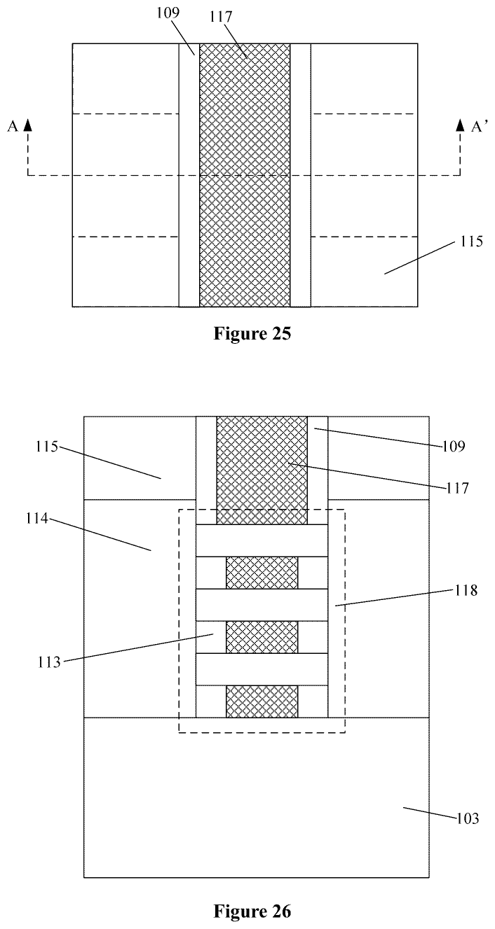

Reference is made to FIGS. 25 and 26. FIG. 25 is a top view, and FIG. 26 is a cross-sectional view under cutting line AA′ in FIG. 25. The first gate structure 117 and the first channel layer 118 are formed in the gate opening 116. The first gate structure 117 is located on the surface of the first channel layer 118.

In one embodiment, the first channel layer 118 comprises a fin located on the first surface.

In another embodiment, the first channel layer comprises multiple stacking layers of nanowires located on the first surface. Each pair of adjacent layers in the multiple stacking layers is spaced apart.

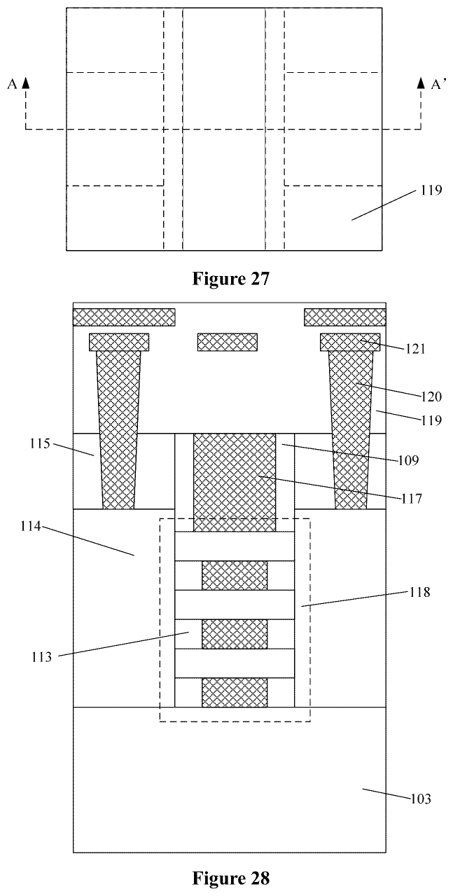

Reference is made to FIGS. 27 and 28. FIG. 27 is a top view, and FIG. 28 is a cross-sectional view under cutting line AA′ in FIG. 27. After the first gate structure 117 and the first channel layer 118 have been formed, a first dielectric layer 119 is formed on a surface of the third dielectric layer 114 and the first gate structure 117. A second conductive plug 120 is then formed in the first dielectric layer 119. A second interconnection layer 121 is formed on the second conductive plug 120, and the second interconnection layer 121 is electrically connected to the first source-drain epitaxial layer 114 and/or the first gate structure 117. The second conductive plug 120 is electrically connected to the second interconnection layer 121.

Herein the first transistor structure and the second transistor structure, which would be provided later, are bonded to opposite sides of the substrate 103. In comparison with a case in which two transistor structures are bonded to the same side, a distance between the second transistor structure and the second interconnection layer 121 is smaller. Hence, an integration degree of the semiconductor structure is increased.

Since the second conductive plug 120 and the second interconnection layer 121 are disposed on the first surface of the substrate 103, there is a large space for arranging the first transistor structure and the second transistor structure. A depth of the second conductive plug 120 can be reduced, and a voltage loss on the plug is thus reduced in the semiconductor structure.

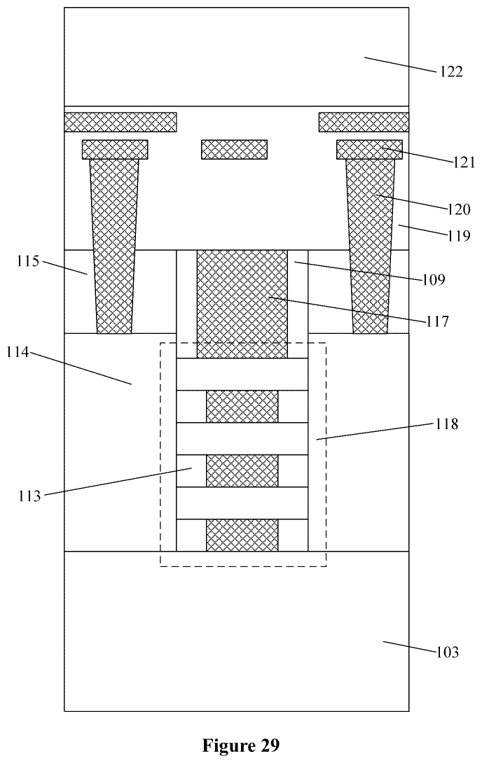

Reference is made to FIG. 29. The structure as shown in FIG. 29 is basically identical to that as shown in FIG. 28. After the second interconnection layer 121 has been formed, a first bonding layer 122 may be formed on a surface of the second interconnection layer 121.

The first bonding layer 122 is configured to bond the first transistor structure and a carrier wafer 123.

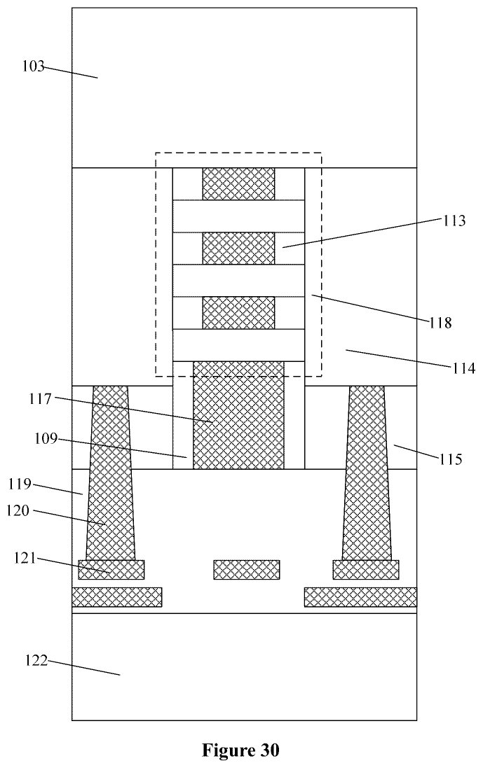

Reference is made to FIG. 30. The substrate 103 and the first transistor structure are flipped (upside-down as shown in FIG. 30).

The flipping facilitates bonding the second transistor structure to the second surface of the substrate 103 in subsequent steps.

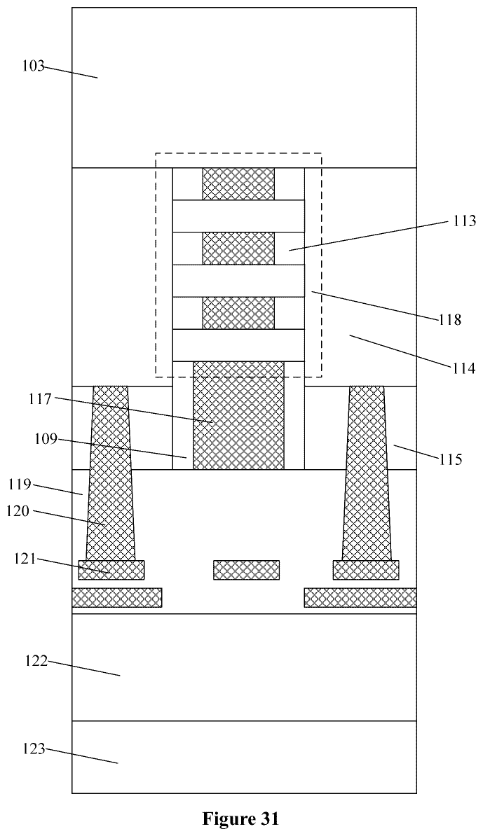

Reference is made to FIG. 31. The carrier wafer 123 is provided. The carrier wafer 123 and the first bonding layer 122 are connected through, so that the first transistor structure is bonded to a surface of the carrier wafer 123.

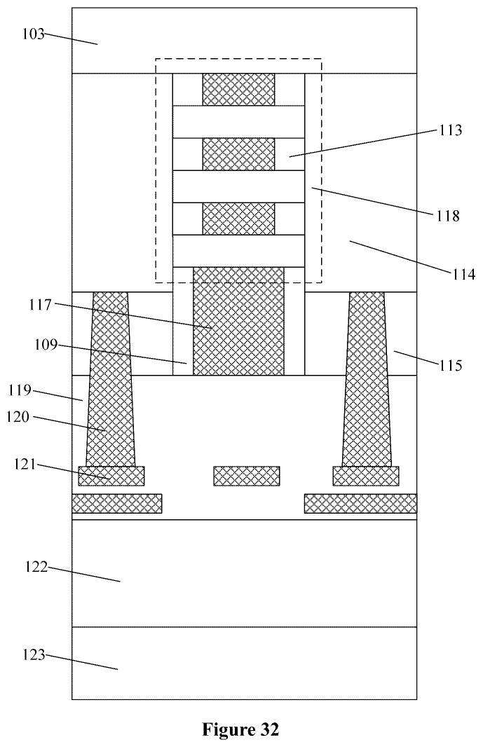

Reference is made to FIG. 32. The substrate 103 is thinned from the second surface toward the first surface.

The thinning may be implemented through mechanical polishing, chemical polishing, fluid polishing, chemical mechanical polishing, or the like. In an embodiment, the thinning comprises chemical mechanical polishing. Unlike traditional purely mechanical or purely chemical polishing methods, the chemical mechanical polishing combines chemical and mechanical actions to suppress surface damages (which are caused by pure mechanical polishing) and achieve higher polishing speed, better surface flatness, and higher polishing consistency (in view of pure chemical polishing).

In an embodiment, a thickness of the thinned substrate 103 ranges from 10 nm to 100000 nm.

The thinning reduces the thickness of the substrate 103, and hence reduces a depth of the first conductive plug 128 (which is to be formed in subsequent steps). A distance between the first transistor structure and the second transistor structure, as well as a distance between the first transistor structure and a first interconnection layer 130, is also reduced. The integration degree of the semiconductor structure is further improved.

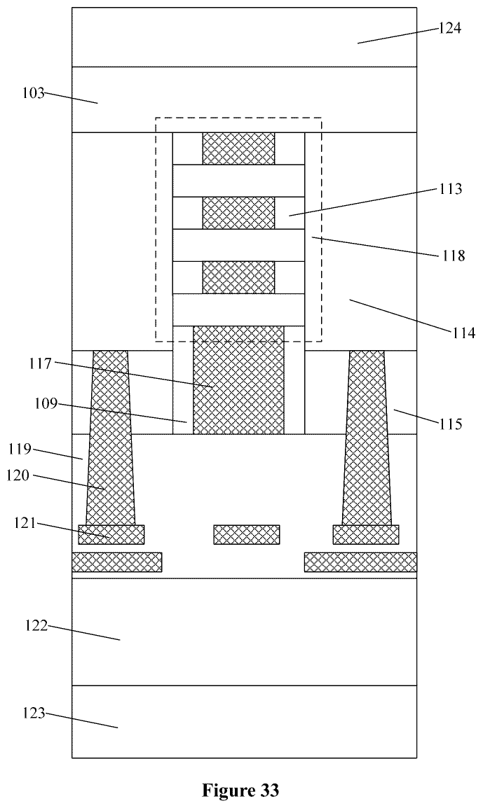

Reference is made to FIG. 33. After the thinning, an isolation dielectric layer 124 may be formed on the second surface.

In an embodiment, a thickness of the isolation dielectric layer 124 ranges from 1 nm to 10000 nm.

The isolation dielectric layer 124 serves as a dielectric layer between the first transistor structure and the second transistor structure.

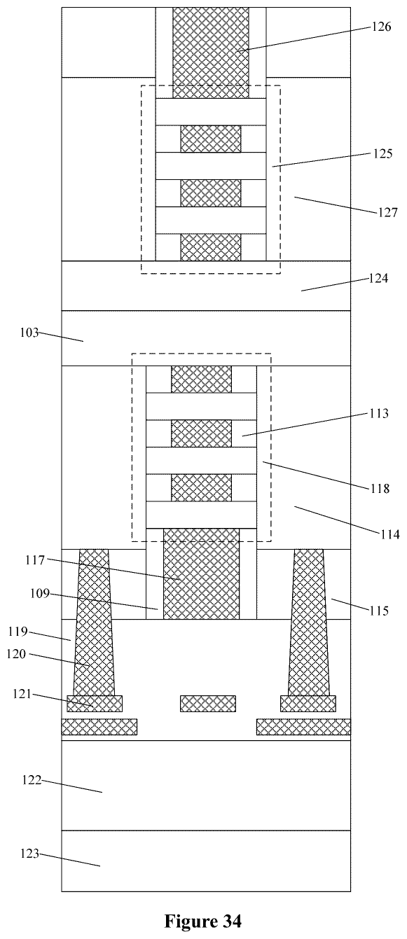

Reference is made to FIG. 34. The second transistor structure is provided. The second transistor structure is bonded to the second surface of the substrate 103. The second transistor structure comprises a second channel layer 125 located on the second surface, a second gate structure 126 located on a surface of the second channel layer 125, and a second source-drain epitaxial layer 127 located on two lateral sides of the second gate structure 126.

In an embodiment, the second transistor structure is bonded to a surface of the isolation dielectric layer 124.

A material of the second transistor structure may comprises silicon, germanium, silicon germanium, indium gallium zinc oxide, and carbon nanotubes.

In an embodiment, temperature of the bonding is less than 500° C. That is, bonding of the transistor structures is implemented at low temperature.

In one embodiment, the second channel layer 125 comprises a fin located on the second surface.

In another embodiment, the second channel layer 125 comprises multiple stacking layers of nanowires. Each pair of adjacent layers in the multiple stacking layers is spaced apart.

Hence, the first transistor structure and the second transistor structure are arranged on opposite sides of the substrate 103. In comparison with the “same side” arrangement, the distance between the first transistor structure and the second transistor structure, as well as the distance between the first transistor structure and the first interconnection layer 130, becomes smaller, which increases the integration degree of the semiconductor structure. Moreover, the distance between the second transistor structure and the second interconnection layer 121 is also reduced, which further increases the integration degree of the semiconductor structure.

Since the second conductive plug and the second interconnection layer are located on the first surface of the substrate, there is an adequate space for arranging the first transistor structure and the second transistor structure. A depth of the second conductive plug is smaller, and hence the voltage loss on the plug is reduced in the semiconductor structure.

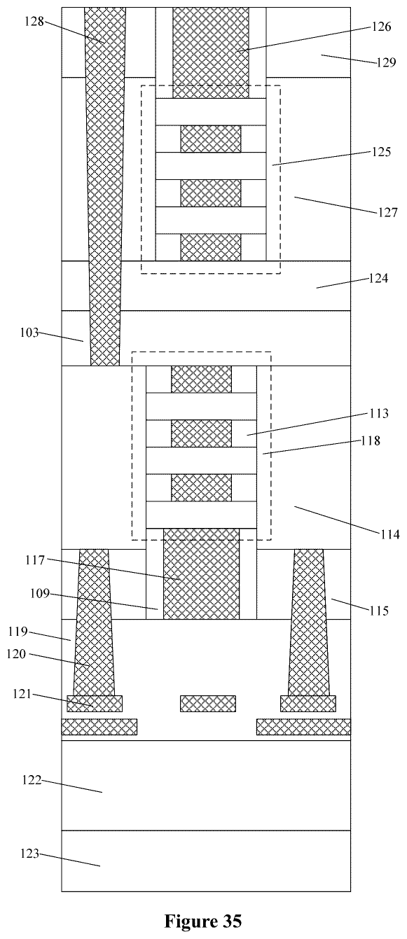

Reference is made to FIG. 35. In an embodiment, after the first transistor structure and the second transistor structure have been bonded together, a first conductive plug 128 is formed in the second source-drain epitaxial layer 127 and the substrate 103. The first conductive plug 128 is electrically connected to the first source-drain epitaxial layer 114.

In an embodiment, the method further comprises a following step before forming the first conductive plug 128. A second dielectric layer 129 is formed on a surface of the second source-drain epitaxial layer 127. The first conductive plug 128 is further located in the second dielectric layer 129.

The first conductive plug 128 is electrically connected to the first source-drain epitaxial layer 114 and the first interconnection layer 130 that is formed in a subsequent step. Thereby, the first transistor structure and the second transistor structure are interconnected.

In an embodiment, the method further comprises a following step. The first conductive plug is formed in the second source-drain epitaxial layer, the substrate, and the first source-drain epitaxial layer.

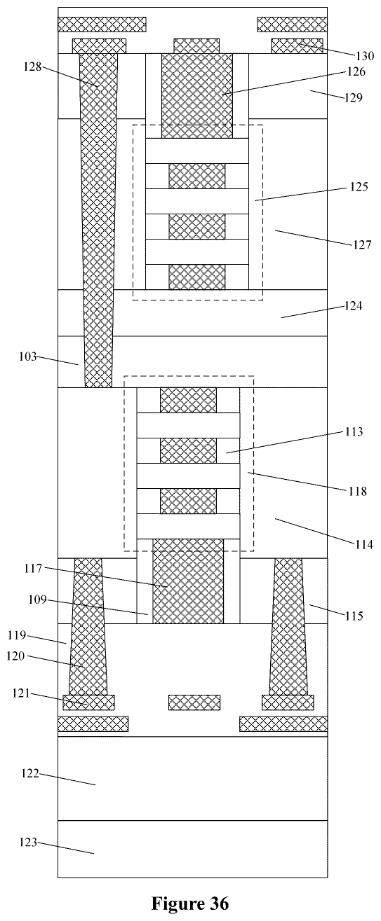

Reference is made to FIG. 36. The first interconnection layer 130 is formed on the first conductive plug 128 and the second gate structure 126. The first interconnection layer 130 is electrically connected to the first conductive plug 128.

Hence, the first transistor structure and the second transistor structure are arranged on opposite sides of the substrate 103. In comparison with the “same side” arrangement, the distance between the first transistor structure and the second transistor structure, as well as the distance between the first transistor structure and the first interconnection layer 130, becomes smaller, which increases the integration degree of the semiconductor structure. Moreover, the distance between the second transistor structure and the second interconnection layer 121 is also reduced, which further increases the integration degree of the semiconductor structure. Since the second conductive plug and the second interconnection layer are located on the first surface of the substrate, there is an adequate space for arranging the first transistor structure and the second transistor structure. A depth of the second conductive plug is smaller, and hence the voltage loss on the plug is reduced in the semiconductor structure.

A semiconductor structure corresponding to the foregoing method is provided according to an embodiment of the present disclosure. Reference is made to FIG. 36. The semiconductor structure comprises a substrate 103, a first transistor structure, a second transistor structure, a first conductive plug 128, and a first interconnection layer 130. The substrate 103 comprises a first surface and a second surface opposite to each other. The first transistor structure is disposed on the first surface. The first transistor structure comprises a first channel layer 118 disposed on the first surface, a first gate structure 117 disposed on a surface of the first channel layer 118, and a source-drain epitaxial layer 114 disposed on two lateral sides of the first gate structure 117. The second transistor structure is disposed on the second surface. The second transistor structure comprises a second channel layer 125 disposed on (e.g., bonded on) the second surface, a second gate structure 126 disposed on a surface of the second channel layer 125, and a second source-drain epitaxial layer 127 disposed on two lateral sides of the second gate structure 126. The first conductive plug 128 is disposed in the second source-drain epitaxial layer 127 and the substrate 103. The first conductive plug 128 is electrically connected to the first source-drain epitaxial layer 114. The first interconnection layer 130 is disposed on the first conductive plug 128 and the second transistor structure. The first interconnection layer 130 is electrically connected to the first conductive plug 128.

Herein substrate 103 has the first surface and the second surface that are opposite to each other.

In an embodiment, a thickness of the substrate 103 ranges from 10 nm to 100000 nm.

In an embodiment, a material of the substrate 103 comprises silicon, silicon carbide, silicon germanium, silicon on insulator (SOI), or germanium on insulator (GOI).

In an embodiment, the material of the substrate 103 is silicon.

In an embodiment, the substrate 103 comprises a well region on which the first transistor structure is located.

In an embodiment, the substrate 103 comprises a base and a bottom structure located on the base. The first channel layer 118 is disposed on the bottom structure.

Herein the first transistor structure located on the first surface comprises the first channel layer 118, the first gate structure 117, and the first source-drain epitaxial layer 114.

In an embodiment, the first channel layer 118 comprises a fin disposed on the first surface.

In another embodiment, the first channel layer 118 comprises multiple stacking layers of nanowires disposed on the first surface. Each pair of adjacent layers in the multiple stacking layers is spaced apart.

In an embodiment, the semiconductor structure comprises a second interconnection layer 121 located on the first surface of the substrate 103. The second interconnection layer 121 is electrically connected to the first source-drain epitaxial layer 114 and/or the first gate structure 117.

In an embodiment, the semiconductor structure comprises a first dielectric layer 119 and a second conductive plug 120. The first dielectric layer 119 is located on the first source-drain epitaxial layer 114. The second conductive plug 120 is located in the first dielectric layer 119 and is electrically connected to the second interconnection layer 121.

Herein the second transistor structure located on the second surface comprises the second channel layer 125, the second gate structure 126, and the second source-drain epitaxial layer 127.

In an embodiment, a material of the second transistor structure comprises silicon, germanium, silicon germanium, indium gallium zinc oxide, and carbon nanotubes.

In an embodiment, the second channel layer 125 comprises a fin disposed on the second surface.

In another embodiment, the second channel layer 125 comprises multiple stacking layers of nanowires disposed on the first surface. Each pair of adjacent layers in the multiple stacking layers is spaced apart.

In an embodiment, the semiconductor structure further comprises an isolation dielectric layer 124 disposed between the second surface and the second source-drain epitaxial layer 127.

In an embodiment, a thickness of the isolation dielectric layer 124 ranges from 1 nm to 10000 nm.

Herein the first conductive plug 128 in the second source-drain epitaxial layer 127 and the substrate 103 is electrically connected to the first source-drain epitaxial layer 114.

In an embodiment, the semiconductor structure further comprises a second dielectric layer 129 disposed on a surface of the second source-drain epitaxial layer 127. The first conductive plug 128 is further disposed in the second dielectric layer 129.

Herein the first interconnection layer 130 is electrically connected to the first conductive plug 128.

In an embodiment, the first conductive plug 128 (or a third conductive plug in the semiconductor device) runs through the second source-drain epitaxial layer 127, the substrate 103, and the first source-drain epitaxial layer 114.

In an embodiment, the semiconductor structure further comprises an isolation structure 107 disposed on the substrate 103, and a part of the first gate structure 117 is disposed on a surface of the isolation structure 107.

In an embodiment, the semiconductor structure further comprises spacers 109 disposed on two lateral sides of the first gate structure 117.

In an embodiment, the semiconductor structure further comprises a first bonding layer 122 disposed between the second interconnection layer 121 and a carrier wafer 123.

Hereinabove embodiments of the present disclosure are disclosed, and the embodiments are not intended for limiting the present disclosure. Those skilled in the art can make various changes and modifications without departing from the spirit and the scope of the present disclosure. Therefore, the protection scope of the present disclosure shall be subject to the scope defined by the claims.

1. A semiconductor structure comprises:
a substrate, comprising a first surface and a second surface opposite to each other;
a first transistor structure disposed on the first surface, wherein the first transistor structure comprises:
a first channel layer disposed on the first surface,
a first gate structure disposed on a surface of the first channel layer, and
a first source-drain epitaxial layer disposed on two lateral sides of the first gate structure;
a second transistor structure disposed on the second surface, wherein the second transistor structure comprises:
a second channel layer disposed on the second surface,
a second gate structure disposed on a surface of the second channel layer, and
a second source-drain epitaxial layer disposed on two lateral sides of the second gate structure;
a first conductive plug disposed in the second source-drain epitaxial layer and the substrate, wherein the first conductive plug is electrically connected to the first source-drain epitaxial layer; and
a first interconnection layer disposed on at a side of the second transistor structure away from the second surface, wherein the first interconnection layer is electrically connected to the first conductive plug.

2. The semiconductor structure according to claim 1, wherein the first channel layer comprises a first fin disposed on the first surface.

3. The semiconductor structure according to claim 1, wherein the first channel layer comprises a plurality of first stacking layers of nanowires disposed on the first surface, and each pair of adjacent layers in the plurality of first stacking layers is spaced apart.

4. The semiconductor structure according to claim 1, wherein the second channel layer comprises a second fin disposed on the second surface.

5. The semiconductor structure according to claim 1, wherein the second channel layer comprises a plurality of second stacking layers of nanowires disposed on the second surface, and each pair of adjacent layers in the plurality of second stacking layers is spaced apart.

6. The semiconductor structure according to claim 1, further comprising:
a second interconnection layer disposed at a side of the first transistor structure away from the first surface, wherein the second interconnection layer is electrically connected to one or both of the first source-drain epitaxial layer and the first gate structure.

7. The semiconductor structure according to claim 6, further comprising:
a first dielectric layer disposed on a surface of the first source-drain epitaxial layer; and
a second conductive plug disposed in the first dielectric layer, wherein the second conductive plug is electrically connected to the second interconnection layer.

8. The semiconductor structure according to claim 1, further comprising:
an isolation dielectric layer disposed between the second surface of the substrate and the second source-drain epitaxial layer.

9. The semiconductor structure according to claim 1, further comprising:
a second dielectric layer disposed on a surface of the second source-drain epitaxial layer, wherein the first conductive plug is further disposed in the second dielectric layer.

10. The semiconductor structure according to claim 1, further comprising a third conductive plug, wherein the third conductive plug running through the second source-drain epitaxial layer, the substrate, and the first source-drain epitaxial layer.

11. The semiconductor structure according to claim 1, further comprising:
an isolation structure disposed on the substrate, wherein a part of the first gate structure is disposed on a surface of the isolation structure.

12. A method for manufacturing a semiconductor structure, comprising:
providing a substrate comprising a first surface and a second surface that are opposite to each other;
providing a first transistor structure on the first surface, wherein the first transistor structure comprises:
a first channel layer disposed on the first surface,
a first gate structure disposed on a surface of the first channel layer, and
a first source-drain epitaxial layer disposed on two lateral sides of the first gate structure;
providing a second transistor structure on the second surface, wherein the second transistor structure comprises:
a second channel layer disposed on the second surface,
a second gate structure disposed on a surface of the second channel layer, and
a second source-drain epitaxial layer disposed on two lateral sides of the second gate structure;
providing a first conductive plug in the second source-drain epitaxial layer and the substrate, wherein the first conductive plug is electrically connected to the first source-drain epitaxial layer; and
providing a first interconnection layer on a side of the second transistor structure away from the second surface, wherein the first interconnection layer is electrically connected to the first conductive plug.

13. The method according to claim 12, wherein:
providing the second transistor structure on the second surface of the substrate comprises bonding the second channel layer to the second surface; and
after providing the first transistor structure on the first surface and before providing the second transistor structure on the second surface, the method further comprises:
flipping an integral structure comprising the first transistor structure and the substrate.

14. The method according to claim 13, wherein providing the first channel layer comprises:
providing an initial substrate;
forming initial stacking layers on a surface of the initial substrate;
forming a first mask layer on a surface of the initial stacking layers;
patterning the initial stacking layers and the initial substrate with masking of the first mask layer to form the substrate and an initial first channel layer located on a surface of the substrate, wherein the initial first channel layer comprises at least one channel material layer and at least one sacrificial material layer that are overlapped and alternately arranged;
forming an isolation structure on the substrate;
forming a dummy gate and spacers on the initial first channel layer, wherein the spacers are located on two lateral sides of the dummy gate;
forming a source-drain opening in the initial first channel layer after forming the dummy gate;
forming the first source-drain epitaxial layer in the source-drain opening;
removing, after forming the first source-drain epitaxial layer, the dummy gate and the at least one sacrificial material layer to form a gate opening; and
forming the first gate structure in the gate opening.

15. The method according to claim 14, wherein after forming the first gate structure and the first channel layer, the method further comprises:
forming a first dielectric layer at a side of the first transistor structure away from the first surface;
forming a second conductive plug in the first dielectric layer; and
forming a second interconnection layer on the second conductive plug, wherein the second interconnection layer is electrically connected to one or both of the first source-drain epitaxial layer and the first gate structure, and the second conductive plug is electrically connected to the second interconnection layer.

16. The method according to claim 15, wherein after flipping the integral structure comprising the substrate and the first transistor structure and before providing the second transistor structure on the second surface of the substrate, the method further comprises:
forming a first bonding layer on a surface of the second interconnection layer;
bonding a carrier wafer to the first bonding layer;
thinning the substrate from the second surface toward the first surface; and
forming an isolation dielectric layer on the second surface after the thinning.

17. The method according to claim 16, wherein the second transistor structure is bonded to a surface of the isolation dielectric layer away from the second surface.

18. The method according to claim 13, wherein a temperature of the bonding is less than 500° C.

19. The method according to claim 12, further comprising:
forming a third conductive plug that runs through the second source-drain epitaxial layer, the substrate, and the first source-drain epitaxial layer.
